(19) United States
(12) Patent Application Publication
(10) Pub. No.: US 2023/0220588 A1
(43) Pub. Date: Jul. 13, 2023

(54) METHOD OF FORMING AN EPITAXIAL STACK ON A PLURALITY OF SUBSTRATES

(71) Applicant: ASM IP Holding B.V., Almere (NL)

(72) Inventors: Steven Van Aerde, Tielt-Winge (BE); Wilco Verweij, Nijkerk (BE); Dieter Pierreux, Pepingen (BE); Kelly Houben, Lubbeek (BE); Bert Jongbloed, Dud-Heverlee (BE); Peter Westrom, Payson, AZ (US)

(21) Appl. No.: 18/153,254

(22) Filed: Jan. 11, 2023

Related U.S. Application Data
(60) Provisional application No. 63/299,212, filed on Jan. 13, 2022.

(51) Int. Cl. C30B 29/68; H01L 21/677; H01L 21/02; C30B 25/16; C30B 29/06; C30B 29/52

(52) U.S. Cl. CPC C30B 29/68; H01L 21/67742; H01L 21/02532; H01L 21/0245; H01L 21/02507; H01L 21/0262; C30B 25/165; C30B 29/06; C30B 29/52; H01L 21/02381; H01L 21/02433

(57) ABSTRACT

A method of forming an epitaxial stack on a plurality of substrates is provided. In a preferred embodiment, the method comprises providing a semiconductor processing apparatus. This semiconductor processing apparatus comprises a process chamber and a carousel for stationing a wafer boat before or after processing in the process chamber. The method further comprises loading the wafer boat into the process chamber, the wafer boat comprising the plurality of substrates. The method further comprises processing the plurality of substrates in the process chamber, thereby forming, on the plurality of substrates, the epitaxial stack. This epitaxial stack has a pre-determined thickness. The processing comprises unloading the wafer boat, one or more times, from the process chamber to the carousel until the epitaxial stack reaches the pre-determined thickness.

### TECHNICAL FIELD OF INVENTION

The present disclosure relates to the field of semiconductor processing. In particular, it relates to processing methods for forming an epitaxial stack on a plurality of substrates.

### BACKGROUND OF THE DISCLOSURE

Formation of films using epitaxy is one of the crucial processing steps in semiconductor manufacturing. It may become even more important as the semiconductor industry is trying to keep up with scaling in order for the manufacturing of semiconductor devices to continue and particularly, when facing the limits of scaling. This may require the formation of thicker epitaxial stacks with less challenges posed in terms of the processing apparatus and in terms of the overall semiconductor manufacturing regarding throughput and yield.

One significant field of interest regarding the formation of epitaxial stacks, in particular the formation of thicker epitaxial stacks, lies in the manufacturing of 3DDRAM devices as a remedy to cope with the limits of scaling and to be able to further manufacture memory devices

Therefore, there is a need in the art for forming epitaxial stacks for helping to improve the manufacturing of 3DDRAM devices without jeopardizing manufacturing throughout and yield.

### SUMMARY OF THE DISCLOSURE

It is an object of the present disclosure to provide improved methods for forming an epitaxial stack on a plurality of substrates. More specifically, certain embodiments may provide improved methods of forming thicker epitaxial stacks on the plurality of substrates, while substrate damage or substrate breakage is reduced. To at least partially achieve this goal, the present disclosure may provide a method as defined in the independent claims. Further embodiments of the method are provided in the dependent claims

In a first aspect, the present disclosure relates to a method for forming an epitaxial stack on a plurality of substrates. The method may comprise providing a semiconductor processing apparatus. This semiconductor processing apparatus may comprise a process chamber and a carousel for stationing a wafer boat before or after processing in the process chamber. The method may also comprise loading the wafer boat into the process chamber, the wafer boat comprising the plurality of substrates. The method may also comprise processing the plurality of substrates in the process chamber, thereby forming, on the plurality of substrates, the epitaxial stack. This epitaxial stack may have a pre-determined thickness. The processing may comprise unloading the wafer boat, one or more times, from the process chamber to the carousel until the epitaxial stack reaches the pre-determined thickness.

The inventive method presented in the present disclosure may advantageously overcome that the plurality of substrates comprised in the wafer boat do not suffer from sticking or in other words, getting attached to the wafer boat.

It may also be an advantage of the embodiments of the present disclosure that intervening the processing of the plurality of substrates at incremental thicknesses during the formation of the epitaxial stack may allow for having a better control on overcoming the sticking of the substrates or in other words, on their getting attached to the wafer boat.

Thus, it may further be an advantage of embodiments of the present disclosure that substrate damage or substrate breakage that may be due to substrate sticking or due to substrate attachment to the wafer boat, thereby, challenging the integrity of the substrates that can thus, be avoided while unloading the substrates from the wafer boat after the epitaxial stack is formed on the plurality of substrates.

It may further be an advantage of embodiments of the present disclosure that it may allow for forming a thicker epitaxial stack on the plurality of substrates. Furthermore, it may be an advantage of the embodiments of the present disclosure that the formation of the thicker epitaxial stack may be achieved without jeopardizing the integrity of the substrates through substrate damage or substrate breakage while unloading from the wafer boat after the formation of the thicker epitaxial stack.

Forming a thicker epitaxial stack according to embodiments of the present disclosure may further be advantageous in the manufacturing of semiconductor devices, particularly for 3DDRAM devices, as it may open a route to provide a remedy against the limits of planar scaling of these devices. This may further contribute to improving commercial success.

It may also be an advantage of the embodiments of the present disclosure that monitoring of the evolution of the thickness of the epitaxial stack can be achieved during the formation of the epitaxial stack. This may allow for achieving the thickness of the epitaxial stack accurately.

It may further be an advantage of the embodiments of the present disclosure that it may allow for preserving the integrity of the epitaxial stack during its formation despite the fact that the processing on the plurality of substrates is being intervened. This may then, allow for forming the epitaxial stack with reduced probability of having defects or damage on the epitaxial stack.

It may further be an advantage of embodiments of the present disclosure that it may allow for reducing cost of semiconductor processing, thereby providing economic processing since plurality of substrates may be processed together in one and the same process run and in one and the same process chamber.

In a second aspect, the present disclosure relates to a non-transitory computer readable medium. The non-transitory computer readable medium may comprise instructions, which, when executed by a controller of a semiconductor processing apparatus, comprising a process chamber and a carousel, may cause the semiconductor processing apparatus to perform the operations of loading a wafer boat into the process chamber, the wafer boat comprising a plurality of substrates, and processing the plurality of substrates in the process chamber, thereby forming, on the plurality of substrates, an epitaxial stack, the epitaxial stack having a pre-determined thickness, wherein the processing may comprise unloading the wafer boat, one or more times, from the process chamber to the carousel until the epitaxial stack reaches the pre-determined thickness.

It may be an advantage of the second aspect of the present disclosure that the controller may cause the semiconductor processing apparatus to process the plurality of substrates in such a way that after completion of the processing, a probability of substrate damage or substrate breakage is reduced when the plurality of substrates are being unloaded from the wafer boat. This may advantageously be due to the fact that unloading the wafer boat, one or more times, from the process chamber to the carousel until the epitaxial stack reaches the pre-determined thickness may allow for creating a chance for getting the substrates detached from the wafer boat supports.

Reducing the probability of substrate damage or substrate breakage may in turn advantageously provide for improvement in process throughput, process yield. This may further be particularly advantageous in the manufacturing of three-dimensional dynamic random access memory (3DDRAM) devices. Furthermore, it may further be advantageous regarding the overall improvement in the throughput and yield of semiconductor manufacturing. Due to the reduced probability of substrate damage or substrate breakage, occurrence of unplanned maintenance cycles may be avoided thereby additionally contributing to the improvement in individual process and overall semiconductor manufacturing throughput and yield.

In a third aspect, the present disclosure relates to a data processing system. The data processing system may comprise a processor configured to perform the steps of loading a wafer boat into the process chamber comprised in a semiconductor processing apparatus, the wafer boat comprising a plurality of substrates, and processing the plurality of substrates in the process chamber, thereby forming, on the plurality of substrates, an epitaxial stack, the epitaxial stack having a pre-determined thickness, wherein the semiconductor processing apparatus may further comprise a carousel and wherein the processing may comprise unloading the wafer boat, one or more times, from the process chamber to the carousel until the epitaxial stack reaches the pre-determined thickness.

It may be an advantage of the third aspect that it may advantageously allow for obtaining a plurality of substrates having reduced probability for substrate damage or substrate breakage after processing is completed. This may in turn, improve the process throughput and process yield as well as improving the overall throughout and overall yield for the semiconductor manufacturing. It may further provide the advantage of better scheduling of the maintenance cycles of the semiconductor processing apparatus due to the reduced probability of substrate damage or substrate breakage, which may be unforeseen.

The concepts presented in this disclosure are believed to represent new developments in this field. Departures from prior art practices are included in the present concepts, thereby resulting in improved methods.

The above and other characteristics, features and advantages of the present disclosure will be clearly understood from the following detailed description that is to be considered together with the drawings included. This description is given for the sake of example only, without limiting the scope of the disclosure. The reference figures referred to below relate to the drawings included. These drawings illustrate, by way of example, the principles of the disclosure.

Particular and preferred aspects of the disclosure are set out in the accompanying independent and dependent claims. Features from the dependent claims may be combined with features of other dependent claims as appropriate and not as just set out in the claims.

### BRIEF DESCRIPTION OF THE FIGURES

The following illustrative and non-limiting detailed description will help to better understand the above, as well as additional objects, features and advantages of the present inventive concept. Reference is also made to the drawings included. Like reference numbers will be used for like elements in the drawings unless stated otherwise

FIG. 1: shows a flowchart of an exemplary method according to embodiments of the first aspect of the present disclosure.

FIG. 2: shows another flowchart of an exemplary method according to embodiments of the first aspect of the present disclosure.

FIG. 3: is a schematic cross-section of the epitaxial stack obtained according to embodiments of the first aspect of the present disclosure.

FIG. 4a to FIG. 4e: is a schematic cross-section of the formation of the epitaxial stack according to embodiments of the first aspect of the present disclosure.

### DETAILED DESCRIPTION OF THE DISCLOSURE

The present disclosure will be described with respect to particular embodiments and with reference to certain drawings. However, the disclosure is not limited thereto but only by the claims. The dimensions in the drawings do not correspond to actual reductions to practice the disclosure. The size of some of the elements may not be drawn to scale, in the drawings, for illustrative purposes. Thus, the drawings described are only schematic and are non-limiting.

Reference throughout the specification to “embodiments” in various places are not necessarily all referring to the same embodiment, but may. Furthermore, the particular features, structures or characteristics maybe combined in any suitable manner from the disclosure, in one or more embodiments, as would be apparent to one of the ordinary skill in the art.

Reference throughout the specification to “some embodiments” means that a particular structure, feature or step described in connection with these embodiments is included in some of the embodiments of the present disclosure. Thus, phrases appearing such as “in some embodiments” in different places throughout the specification are not necessarily referring to the same collection of embodiments, but may.

It is to be noticed that the term “comprising”, used in the claims, should not be interpreted as being restricted to the means listed thereafter. It does not exclude other elements, features, steps or components. It is thus, to be interpreted as specifying the presence of the stated elements, features, steps or components as referred to. However, it does not prevent one or more other elements, features, steps or components, or groups thereof from being present or being added.

It is to be noticed that the term “comprise substantially” used in the claims refers that further components than those specifically mentioned can, but not necessarily have to, be present, namely those not materially affecting the essential characteristics of the material, compound, or composition referred to.

It should be understood that in the description of exemplary embodiments of the disclosure, various features of the disclosure are sometimes grouped together in a single embodiment, figure or description in order to help to understand one or more of the inventive aspects. The claims following the detailed description are incorporated into the detailed description, with each claim standing on its own as a separate embodiment of the disclosure.

Some embodiments described herein include some but not other features included in other embodiments. However, combinations of features of different embodiments and formation of different embodiments are meant to be within the scope of the disclosure, as would be understood by those in the art. In the claims included, any of the claimed embodiments can, for example, be used in any combination.

The terms first, second, third and the like appearing in the description and the claims, are there to help in distinguishing between similar elements, similar features, similar steps or similar components. Thus, they are not used necessarily for describing an order or a sequence in any manner. It is thus, to be understood that the embodiments of the disclosure described in the description are capable of being used in other sequences than the described ones. It is further to be understood that such terms can be interchangeable under suitable conditions.

The following terms are provided solely to help in the understanding of the disclosure.

As used herein and unless provided otherwise, the term “carousel” refers to a rotating table for stationing the wafer boat.

As used herein and unless provided otherwise, the expression “peripheral area” refers to surface area of the epitaxial stack at the circumferential edges of each of the plurality of substrates.

As used herein and unless provided otherwise, the expression “substrate integrity” refers to the level of substrate damage or substrate breakage; i.e.: lower integrity may refer to higher probability of having substrate damage or substrate breakage or higher integrity may refer to lower substrate damage or substrate breakage.

As used herein and unless provided otherwise, the expression “thickness non-uniformity” refers to the variation in thickness of the epitaxial stack across the substrate surface.

As used herein and unless provided otherwise, the expression “poor in terms of pin-holes” refers to the third epitaxial layer having no pin-holes or lower number of pin-holes per surface area such that it does not influence the integrity and materials properties of the third epitaxial layer.

The disclosure will now be described by a detailed description of several embodiments of the disclosure. It is to be understood that other embodiments of the disclosure can be configured according to the knowledge of persons skilled in the art. This can be done without departing from the technical teaching of the disclosure and the disclosure being limited only by the terms of the accompanied claims.

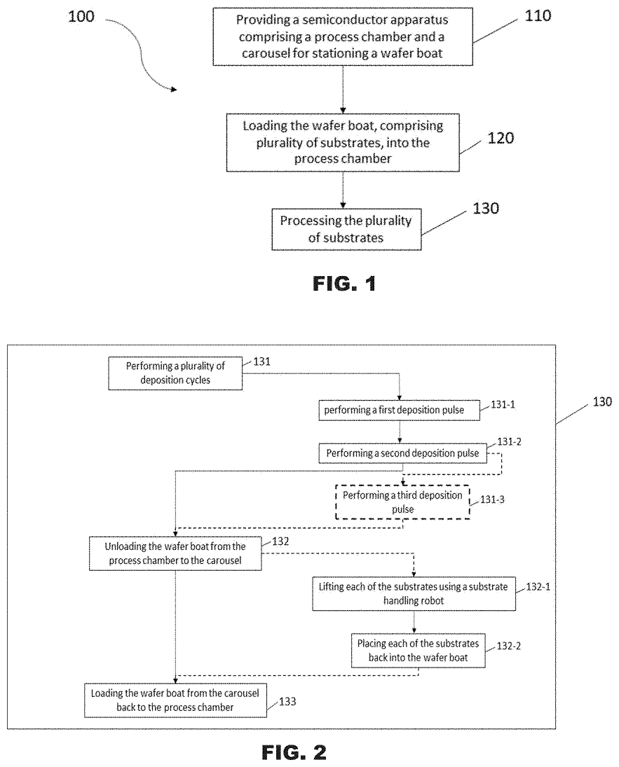

We now refer to FIG. 1 and FIG. 2 representing a flowchart of an exemplary method according to embodiments of the present disclosure.

The method (100) of forming an epitaxial stack on a plurality of substrates may comprise providing (110) a semiconductor processing apparatus. The semiconductor processing apparatus may comprise a process chamber and a carousel for stationing a wafer boat before or after processing in the process chamber.

The method (100) may comprise loading (120) the wafer boat into the process chamber. The wafer boat may comprise a plurality of wafers. The plurality of wafers may be stacked in the vertical direction in the wafer boat. The method may comprise processing (130) the plurality of substrates in the process chamber, thereby forming, on the plurality of substrates, the epitaxial stack, the epitaxial stack having a pre-determined thickness. Being able to process the plurality of substrates in the vertical furnace may be advantageous in improving the overall throughput of the semiconductor manufacturing process since the plurality of substrates can be processed together at once and in one and the same process chamber. The plurality of substrates may be any type of substrate that may be processed in the vertical furnace. In embodiments, the plurality of substrates may be semiconductor substrates. In embodiments, one or more surface layers may be present or may be formed on the substrates. In preferred embodiments, the semiconductor substrates may be Si (100) or Si (111) substrates. In alternative embodiments, the plurality of substrates may be silicon-on-insulator (SOI) substrates, with the silicon layer being a Si (100) or a Si (111) layer.

The processing of the plurality of substrates (130) may comprise unloading (132) the wafer boat, one or more times, from the process chamber to the carousel until the epitaxial stack reaches the pre-determined thickness. Unloading the wafer boat from the process chamber, one or more times, during the processing may allow for reducing the probability of the plurality of substrates getting stuck or in other words, getting glued to the wafer boat. The plurality of substrates may get stuck to the wafer boat as the epitaxial stack is growing. As it grows, the epitaxial stack may, particularly, stick to the wafer boat from the edges of the substrate. Sticking or gluing of the plurality of substrates to the wafer boat may consequently lead to substrate damage or substrate breakage when unloading the substrates from the wafer boat after processing is completed. The chances of the substrates getting stuck or glued to the wafer boat may, particularly, become a concern when forming thicker epitaxial stacks. Thus, the method disclosed in the present invention may advantageously provide reliable substrate processing, without jeopardizing the yield of the process. Furthermore, undesired substrate damage or substrate breakage due to substrate sticking to the wafer boat may lead to downtime of the semiconductor processing apparatus as it would need to undergo maintenance and process qualification before resuming the processing. Therefore, the method disclosed in the present invention may advantageously allow for reducing the risk for unplanned maintenance cycles, thereby also contributing to the process throughput on one hand, and overall semiconductor manufacturing throughput, on the other hand.

The semiconductor processing apparatus may be a horizontal furnace or a vertical furnace.

In preferred embodiments, the semiconductor processing apparatus may be a vertical furnace. The process chamber may thus, extend in a vertical direction and may be configured for accepting the wafer boat in the vertical direction. The vertical furnace may advantageously allow for saving cleanroom space in semiconductor manufacturing environment.

In some embodiments, the processing may further comprise lowering the temperature of the process chamber before unloading the wafer boat from the process chamber. It is to be understood that during the lowering of the temperature of the process chamber, no more epitaxial growth takes place in the process chamber. The temperature may be lowered by a value in the range of 100° C. to 200° C. lower than the process temperature. In embodiments, this temperature may be lowered from at least 100° C. to at most 125° C., or at least 125° C. to at most 150° C., or from at least 150° C. to at most 175° C., or from at least 175° C. to at most 200° C. lower than the process temperature.

This may provide the advantage of creating mechanical stress between the plurality of substrates and the wafer boat, thereby allowing for detachment of the plurality of substrates from the wafer boat when the wafer boat is still in the process chamber. In order to obtain a higher mechanical stress, it may be advantageous that the material of the wafer boat and that of the plurality of substrates are different from each other. As such, due to the difference in coefficient of thermal expansion, a higher mechanical stress may be achieved when the temperature in the process chamber is lowered, thereby better enabling the detachment of the plurality of substrates from the wafer boat when they are still in the process chamber. Thus, in embodiments where the plurality of substrates are silicon substrates, for example, a quartz wafer boat may thus be used.

In embodiments, the plurality of substrates comprised in the wafer boat may be cooled when the wafer boat is stationed on the carousel after being unloaded (132) from the process chamber. Cooling occurs due to the flow of an inert gas over the plurality of substrates when they are stationed on the carousel. The cooling takes place due to the temperature difference between the plurality of substrates and the inert gas that flows. In order to facilitate the cooling of the substrates, in some embodiments, a blower may be used to blow the inert gas over the plurality of substrates. In embodiments, the inert gas may comprise substantially N₂.

In alternative embodiments, the plurality of substrates comprised in the wafer boat may be subjected to a gas having a higher specific heat capacity than N₂, expressed in Joule per gram. kelvin (J/gr.K), at the temperature when the wafer boat is stationed on the carousel after being unloaded (132) from the process chamber. It is to be understood that the velocity of flow of the gas may be increased in order to enhance the cooling effect. In embodiments, the gas having the higher specific heat capacity than N₂ may comprise CO₂. In some embodiments, the gas having the higher specific heat capacity than N₂ may substantially comprise CO₂.

The cooling of the plurality of substrates, occurring on the carousel, may lead to the shrinkage of the plurality of substrates. Shrinking may advantageously help the substrates to get detached from the wafer boat, so that when the wafer boat is loaded back into the process chamber and the processing is resumed, the chances may be that it gets easier to detach the substrates as the epitaxial stack grows thicker.

In embodiments, the wafer boat may comprise a plurality of wafer boat supports for supporting the plurality of substrates . The semiconductor processing apparatus may further comprise a substrate handling robot and the method may further comprise, after unloading the wafer boat from the process chamber to the carousel, lifting (132-1) each of the plurality of substrates using the substrate handling robot. This helps to detach each of the plurality of substrates from the wafer boat supports and thereafter, each of the plurality of substrates may be placed back (132-2) in the wafer boat. The lifting of each of the plurality of substrates may thus, be performed when the wafer boat is stationed on the carousel after being unloaded from the process chamber.

Detaching each of the plurality of substrates from the wafer boat supports using the substrate handling robot may further enhance, or in other words, contribute further to the detachment of the plurality of substrates from the wafer boat supports. This may particularly be advantageous as the epitaxial stack grows thicker and thus, the cooling provided on the carousel alone would not be sufficient to detach the substrates from the wafer boat. The insufficiency may be a result of the increased surface area of contact between each of the substrates and the wafer boat supports at the edges of the substrates due to the epitaxial stack getting thicker, whereby the chances to get stuck or glued to the wafer boat supports may thus, be increased.

In some embodiments, when the wafer boat is unloaded from the process chamber to the carousel, further contribution to the detachment of the plurality of substrates may be done in such a way that all of the substrates may be detached at the same time.

In some embodiments, when the wafer boat is unloaded from the process chamber to the carousel, further contribution to the detachment of the plurality of substrates may be enabled by a mechanism integrated into the wafer boat stack. The plurality of substrates may remain in the wafer boat and they may then be lifted by this mechanism.

In embodiments, the one or more times unloading of the wafer boat from the process chamber may comprise obtaining the thickness of the epitaxial stack until it reaches the pre-determined thickness. The pre-determined thickness may represent the ultimate thickness of the epitaxial stack that is desired to be obtained after processing is completed in the process chamber. Obtaining the thickness of the epitaxial stack may allow for monitoring the evolution of the thickness of the epitaxial stack during the complete processing that is carried out in the process chamber. This monitoring may be executed in several ways.

One way of monitoring may comprise calculating the cumulative thickness of the epitaxial stack obtained before each of the unloading (132) from the process chamber to the carousel. The incremental thickness achieved between two subsequent unloading may be based on the process carried out in the process chamber with specific process parameters. This incremental thickness may be looked up from a calibration curve pertaining to process parameters of the process in question displayed as a function of thickness obtained. This calibration curve may have been created based on various process parameters used in experimental process runs that are pre-executed in the process chamber. This way of monitoring may include the fact that the incremental thickness achieved between two subsequent unloading may be different from one another as well as being the same as one another.

Alternatively, if the incremental thickness achieved between two subsequent unloading is targeted to be the same, each of these incremental thicknesses may be summed up. This summing up may be done automatically by a software integrated within the hardware of the semiconductor processing apparatus or may be manually triggered by an operator operating the semiconductor processing apparatus.

In embodiments, the processing (130) may further comprise loading (133) the wafer boat comprising the cooled plurality of substrates from the carousel back into the process chamber. This may allow for the processing to continue, thereby increasing the thickness of the epitaxial stack towards the pre-determined thickness. It is therefore, to be understood that between the unloading (132) of the wafer boat from the process chamber and loading (133) of the wafer boat back into the process chamber, the wafer boat may remain stationed on the carousel. After loading (133) back into the process chamber is completed, the temperature in the process chamber may be increased in order to reach the process temperature and after reaching stabilized process temperature, the processing in the process chamber may be resumed.

The process temperature may, in embodiments, be monitored by using a thermocouple, that is placed inside the process chamber. The thermocouple may be situated in an upper section of the process chamber and above an upper section of the wafer boat holding the plurality of substrates. In some embodiments, a plurality of thermocouples may be used. Each of the plurality of thermocouples may be placed at differing locations inside the process chamber for allowing a better temperature control inside the process chamber.

In embodiments, the temperature of the process chamber while the wafer boat is being loaded back (133) from the carousel may be at value that is lower than the first or the second deposition temperature. This may provide the advantage of reducing the probability of oxidation of the plurality of substrates. In embodiments, the difference in the temperature of the process chamber between the wafer boat loading and the deposition may be at a value in the range of 100° C. to 200° C. In embodiments, this temperature difference may be from at least 100° C. to at most 125° C., or at least 125° C. to at most 150° C., or from at least 150° C. to at most 175° C., or from at least 175° C. to at most 200° C.

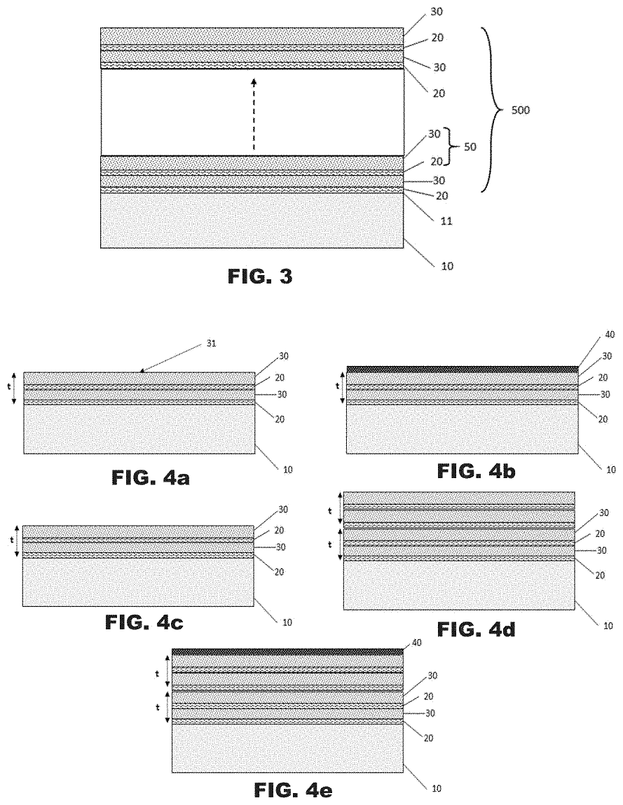

We now refer to FIG. 3, a schematic cross-section of the formation of the epitaxial stack according to embodiments of the present disclosure.

In embodiments, the epitaxial stack (500) may comprise a plurality of epitaxial pairs (50). Each of these epitaxial pairs (50) may comprise a first epitaxial layer (20) and a second epitaxial layer (30), the second epitaxial layer (30) being different than the first epitaxial layer (20) and being stacked alternately and repeatedly with the first epitaxial layer (20). Thus, in the epitaxial stack (50), each of the first epitaxial layers (20) may appear to be sandwiched in between the second epitaxial layers (30) or each of the second epitaxial layers (30) may appear to be sandwiched in between the first epitaxial layers (20).

In embodiments, each of the first epitaxial layers (20) may be in direct contact with each of the second epitaxial layers (30).

Thus, in embodiments, the pre-determined thickness of the epitaxial stack may also refer to the thickness of the total number of epitaxial pairs of the epitaxial stack that is desired to be achieved.

In embodiments, the first epitaxial layer (20) or the second epitaxial layer (30) may be provided on an upper surface (11) of the substrate (10). In preferred embodiments, the first epitaxial layer (20) may be provided on an upper surface (11) of the substrate (10). Before provision of the first epitaxial layer (20) on the substrate (10), the plurality of substrates may be subjected to a pre-clean process. This pre-clean process may be carried out in the same process chamber, where the formation of the epitaxial stack (500) takes place, thus being an in-situ pre-clean process. In alternative embodiments, this pre-clean process may be carried out in a different chamber of the semiconductor processing apparatus, the semiconductor processing apparatus thus, being a cluster tool, after which the wafer boat comprising the plurality of substrates may be transferred to the process chamber of the semiconductor processing apparatus for the formation of the epitaxial stack (500).

In embodiments, the number of epitaxial pairs (50) may be at least 50. In embodiments, the number of the plurality of epitaxial pairs (50) may go up to 550, but not limited thereto. Therefore, in some embodiments, the number of epitaxial pairs (50) may be at least from 50 to at most 150, or at least from 150 to at most 250 or at least from 250 to at most 350, or at least from 350 to at most 450 or at least from 450 to at most 550. This may allow for using the plurality of substrates having such an epitaxial stack for the manufacturing of, particularly, 3DDRAM devices, thereby overcoming the limits of planar scaling of these devices. It may thus, further contribute to commercial success.

In embodiments, at least one of the first epitaxial layer (20) or the second epitaxial layer (30) may have a thickness in the range of 5 nm to 50 nm. Thus, in embodiments, at least one of the first epitaxial layer (20) or the second epitaxial layer (30) may have a thickness in the range of from at least 5 nm to at most 15 nm, or from at least 15 nm to at most 20 nm, or from at least 20 nm to at most 25 nm, or from at least 25 nm to at most 30 nm, or from at least 30 nm to at most 35 nm, or from at least 35 nm to at most 40 nm, or from at least 40 nm to at most 45 nm, or from at least 45 nm to at most 50 nm.

In some embodiments, the thickness of the first epitaxial layer (20) and the second epitaxial layer (30) may be the same, while in some embodiments the thickness of the first epitaxial layer (20) and the second epitaxial layer (30) may be different from one another.

We now refer to FIGS. 4a-4e, a schematic cross-section of the formation of the epitaxial stack according to embodiments of the present disclosure.

In embodiments, the processing (130) may further comprise, before and after each of the unloading (132) of the wafer boat, performing a plurality of deposition cycles (131) until the epitaxial stack (500) has reached a threshold thickness (t) being lower than the pre-determined thickness (FIG. 4a).

This may provide the advantage that when unloading (132) is performed upon reaching this threshold thickness value (t), the probability of the plurality of substrates getting stuck or glued to the wafer boat or the extent to which the plurality of substrates is stuck or glued to the wafer boat may be decreased. This may provide the advantage that upon unloading the wafer boat from the process chamber and while stationing it on the carousel, the cooling effect may be sufficient to detach the plurality of substrates from the wafer boat supports. In case cooling would not provide sufficient detachment, use of the substrate handling robot may provide the required detachment (132-1). As the wafer boat is unloaded upon reaching the threshold value (t), the probability of substrate damage or substrate breakage may advantageously be reduced when the substrate handling robot is further used to detach the substrates from the wafer boat supports.

In embodiments, the threshold thickness may be in the range of 1 μm to 5 μm. In embodiments, the threshold thickness may be from at least 1 μm to at most 1.5 μm, or from at least 1.5 μm to at most 2 μm, or from at least 2 μm to at most 2.5 μm, or from at least 2.5 μm to at most 3 μm, or from at least 3 μm to at most 3.5 μm or from at least 3.5 μm to at most 4 μm, or from at least 4 μm to at most 4.5 μm, or from at least 4.5 μm to at most 5 μm.

It is to be understood that the threshold thickness corresponds to the total thickness of the first (20) and the second (30) epitaxial layers formed, upon which the wafer boat needs to be unloaded from the process chamber (132). In other words, the threshold thickness may also be correlated with a threshold number of epitaxial pairs, upon formation of which the wafer boat needs to be unloaded from the process chamber to the carousel (132).

The threshold value being in this range may allow for incrementally controlling or intervening with the plurality of substrates getting stuck or glued to the wafer boat supports. This may be due to the fact that at the threshold thickness, the surface area of the epitaxial stack at the circumferential edges of each of the plurality of substrates; i.e. the peripheral area, is not large enough to lead to substantial sticking or gluing to the wafer boat, i.e.: to the wafer boat supports. Therefore, the detachment of the plurality of substrates from the wafer boat supports due to the cooling and/or by the substrate handling robot can be achieved without jeopardizing the integrity of the substrates; i.e. without causing substrate damage or substrate breakage.

In between subsequent unloading of the wafer boat from the process chamber, the threshold thickness of the epitaxial stack obtained in the process chamber may be determined.

The determination of the threshold thickness may be based on the duration of the deposition pulses used for forming the epitaxial layers while the plurality of substrates are in the process chamber. To do this, the growth rate of the first (20) and second (30) epitaxial layers may be determined initially. This may be done by creating the calibration curve as mentioned herein that may be based on various process parameters used in experimental process runs that are pre-executed in the process chamber. Consequently, the duration of the deposition pulses may then help for calculating the thickness obtained; i.e.: the threshold thickness. Thus, the threshold thickness may refer to the incremental thickness as mentioned herein.

In embodiments, the wafer boat may further comprise a plurality of grooves; i.e.: slots, for holding the plurality of substrates. These grooves may be formed by a plurality of protruding features extending, along a first axis, from each of the wafer boat supports towards an inner space formed by the wafer boat supports. Each of the plurality of substrates may be positioned or in other words, may be held in place in the wafer boat when they are placed on the protruding features that form the grooves.

In some embodiments, the wafer boat may be such that the plurality of protruding features may be extending from each of the wafer boat supports towards the inner space along a second axis being at an angle, a, with respect to the first axis, the first axis being perpendicular to the wafer boat supports. This may be referred to as an angle-slotted wafer boat. This may provide the advantage of reducing the area of contact between each of the substrates and each of the grooves. Due to the reduced area of contact, the probability of sticking or gluing may consequently be reduced. The reduced probability of sticking or gluing may advantageously lead to each of the plurality of substrates getting detached from the wafer boat supports more easily and faster by the cooling effect provided when the wafer boat is stationed on the carousel and/or when the substrate handling robot is used.

It is to be understood that the higher the angle a is, the less is the number of substrates that may be accommodated in the wafer boat. This is due to the fact that as the angle a is increased, then the distance between each of the slots for holding the substrates may need to be increased in order to avoid that the substrates touch one another and/or to provide that they can still be easily unloaded from the wafer boat without leading to damage to the substrates. A higher angle a may thus, lead to a decrease in throughout of the semiconductor processing apparatus since the number of substrates that can be processed may eventually decrease.

In embodiments, the angle, a, may thus be in the range of 2 to 5 degrees.

In preferred embodiments, the angle is at 3 degrees.

In some embodiments, the plurality of protruding features may be extending towards the inner space formed by the wafer boat supports along the first axis, the first axis being perpendicular to the wafer boat supports. In these embodiments, it may be advantageous to roughen the surface of each of the plurality of protruding features that come in contact with a surface of each of the plurality of substrates. This may allow for reducing the contact area between the surface of the substrates and the protruding features, thereby making it easier to detach the substrates.

A deposition cycle may comprise a first deposition pulse (131-1). This first deposition pulse may comprise a provision of a first reaction gas mixture to the process chamber, thereby forming the first epitaxial layer (20). The deposition cycle may comprise a second deposition pulse (131-2). This second deposition pulse may comprise a provision of a second reaction gas mixture to the process chamber, thereby forming the second epitaxial layer (30), the second reaction gas mixture being different from the first reaction gas mixture.

In embodiments, the first epitaxial layer (20) may comprise a first semiconductor material and the provision of the first reaction gas mixture may comprise providing first semiconductor material precursors. The second epitaxial layer (30) may comprise a second semiconductor material being different than the first semiconductor material and the provision of the second reaction gas mixture may comprise providing a second semiconductor material precursor.

In embodiments, the first semiconductor material precursors may comprise a first germanium-containing compound and a first silicon-containing compound. The second semiconductor material precursor may comprise substantially a second silicon-containing compound.

The first germanium-containing compound may, in embodiments, be a germane. In some embodiments, the germane may be a high order germane. The higher order germane may be a di-germane (Ge₂H₆), a tri-germane (Ge₃H₈) or a tetra-germane (Ge₄H₁₀) as well as other higher order germanes having a general formula of GeₓH_{2X+2}.

In some embodiments, the germane may be a mono-germane.

In some embodiments, the germane may be a halo-germane. The halo-germane has the formula GeHₙX₄₋ₙ, where X is a halogen such as, F, Cl, Br or I and where n is an integer from 0 to 3. The halo-germane may, in embodiments, be a fluoro-germane, a chloro-germane, a bromo-germane or an iodo-germane. The chloro-germane may, in embodiments, be chosen from GeCl₃H, GeCl₄, GeClH₃, GeCl₂H₂, and Ge₂ClH₅.

The first silicon-containing compound and/or the second silicon-containing compound may, in embodiments, be a silane. The silane has a general molecular formula of SiₙH₂ₙ₊₂, n being an integer from at least 1 to at most 20. The silane may, in embodiments, be a mono-silane, a high order silane or a cyclic silane.

High order silanes provide the advantage of forming the epitaxial layer at a lower deposition temperatures than a typical epitaxial layer formation. This is thanks to the presence of the low energy Si—Si bonds. In embodiments, high order silane may be a high order straight chain silane or a high order branched silane. High order straight chain silanes have a general molecular formula of SiₙH₂ₙ₊₂, n being an integer from at least 2 to at most 20. High order branched silanes have a general SiₙH₂ₙ₊₂, where n is an integer from at least 4 to at most 20.

The cyclic silanes or in other words, the cyclo-silanes have a ring structure, thereby having lower Si—Si and Si—H bond strengths. This may therefore provide the advantage of forming epitaxial layers at lower deposition temperatures. They have a general molecular formula of SiₙH₂ₙ, where n is an integer from at least 3 to at most 20, or from at least 5 to at most 10, and it is a silane with a ring structure.

In embodiments, the second semiconductor material comprised in the second epitaxial layer (30) may be Si.

In embodiments, the first semiconductor material comprised in the first epitaxial layer (20) may be Si_{X}Ge_{1-X}, x being 0 or 1. In some embodiments, x may be in the range of 0.15 to 0.30. Thus, in some embodiments, x may be from at least 0.15 to at most 0.2, or from at least 0.2 to at most 0.25, or from at least 0.25 to at most 0.3.

This may allow for providing etch selectivity against the second semiconductor material being Si. Thus, the etch selectivity may be tailored depending on the value of x. Furthermore, it allows for growing the first and the second epitaxial layer with a reduced probability of stress relaxation.

In embodiments, the epitaxial stack may have an exposed upper surface (31) that may be comprised in the second epitaxial layer (30) upon reaching the threshold thickness (t) (FIG. 4a). Thus, when the epitaxial stack (500) reaches the threshold thickness (t), the upper most layer of the epitaxial stack (500), in these embodiments, may be the second epitaxial layer (30) having the exposed upper surface (31). The method may then further comprise, before unloading the wafer boat, at the threshold thickness (t), from the process chamber, performing a third deposition pulse (131-3) as schematically shown in FIG. 2. The third deposition pulse (131-3) may comprise a provision of a third reaction gas mixture to the process chamber, thereby forming a third epitaxial layer (40) on the exposed upper surface (31) of the epitaxial stack (500) (FIG. 4b), the third epitaxial layer (40) being different from the first epitaxial layer (20) and being different from the second epitaxial layer (30). Thus, in these embodiments, the third epitaxial layer (40) may be in direct contact with the exposed upper surface (31) of the second epitaxial layer (30) of the epitaxial stack (500) at the threshold thickness (t).

The thickness of the second epitaxial layer (30), before performing the third deposition pulse, may in some embodiments, correspond to a thickness of the second epitaxial layer (30) that is desired to be formed. While in some embodiments, the third deposition pulse may be performed when the desired thickness of the second epitaxial layer (30) has not yet been achieved.

The provision of the third epitaxial layer (40) on the epitaxial stack at the threshold thickness (t) may provide the advantage of protecting the exposed upper surface (31) when the wafer boat is unloaded from the process chamber (132). The protection provided by the third epitaxial layer (40) may, particularly, be against oxidation of the upper surface (31). Presence of an oxide layer on the exposed upper surface (31) may jeopardize the epitaxial growth when the wafer boat is loaded back into the process chamber (133) after being stationed on the carousel. Even though a pre-clean process, back in the process chamber, may be an option to remove the oxide layer, it may create a risk of damaging the upper surface of the epitaxial stack during and/or completion of the removal the oxide layer.

In embodiments, the third epitaxial layer (40) may comprise a third semiconductor material. The third semiconductor material may be different from the first semiconductor material and different from the second semiconductor material.

In embodiments, the third semiconductor material comprised in the third epitaxial layer (40) may be Ge.

In embodiments, the provision of the third reaction gas mixture may comprise providing a third semiconductor material precursor. The third semiconductor material precursor may comprise substantially a second germanium-containing compound. The second germanium-containing compound may be the same as the first germanium-containing compound or it may be different from the first germanium-containing compound.

Therefore, in embodiments, the second germanium-containing compound may be a germane. In some embodiments, the germane may be a high order germane. The higher order germane may be a di-germane (Ge₂H₆), a tri-germane (Ge₃H₈) or a tetra-germane (Ge₄H₁₀) as well as other higher order germanes having a general formula of GeₓH_{2X+2}.

In some embodiments, the germane may be a mono-germane, GeH₄.

In some embodiments, the germane may be a halo-germane. The halo-germane has the formula GeHₙX₄₋ₙ, where X is a halogen such as, F, Cl, Br or I and where n is an integer from 0 to 3. The halo-germane may, in embodiments, be a fluoro-germane, a chloro-germane, a bromo-germane or an iodo-germane. The chloro-germane may, in embodiments, be chosen from GeCl₃H, GeCl₄, GeClH₃, GeCl₂H₂, and Ge₂ClH₅.

In preferred embodiments, the second germanium-containing compound may be GeH₄ or GeCl₄.

The thickness of the third epitaxial layer (40) may be chosen such that the third epitaxial layer (40) is poor in terms of pin-holes. This allows for providing protection against chemical or physical interaction of the upper surface of the epitaxial stack, onto which the third epitaxial layer is provided, with an ambient that it may be exposed to. Furthermore, the thickness of the third epitaxial layer (40) may be chosen such that the third epitaxial layer does not get fully oxidized, i.e.: oxidation taking place throughout the total thickness, upon being exposed to an oxidizing ambient or to an ambient comprising an oxidizing agent. Absence of full oxidation throughout the total thickness may prevent the oxidation front reaching the interface between the third epitaxial layer (40) and the epitaxial stack or prevent it from moving further down in the epitaxial stack. Oxidation reaching the interface between the third epitaxial layer (40) and the epitaxial stack or occurring further down in the epitaxial stack may, consequently, jeopardize further growth of the epitaxial layers.

In embodiments, the thickness of the third epitaxial layer (40) may be at most 10 nm. In embodiments, the thickness of the third epitaxial layer (40) may be from at least 1 nm to at most 10 nm, or from at least 1 nm to at most 3 nm, or from at least 3 nm to at most 5 nm, or from at least 5 nm to at most 7 nm, or from at least 7 nm to at most 10 nm.

As the thickness of the third epitaxial layer (40) increases, it may pose challenges in terms of process throughput; i.e.: it may be lowered. Lowering of the process throughout may be caused by the longer time it may then take for the removal of the third epitaxial layer (40) before resuming the further growth of the epitaxial layers. Such challenges may start to occur at thicknesses of the third epitaxial layer (40) beyond 10 nm.

In embodiments, the first deposition pulse may be carried out at a first deposition temperature, the second deposition pulse may be carried out at a second deposition temperature, the third deposition pulse may be carried out at a third deposition temperature and the first, the second and the third deposition temperature may be less than 600° C.

In embodiments, the first, the second and the third deposition temperature may be at a temperature in the range of from at least 300° C. to at most 600° C., or from at least 300° C. to at most 350° C., or from at least 350° C. to at most 400° C. or from at least 400° C. to at most 450° C. or from at least 450° C. to at most 500° C. or from at least 500° C. to at most 550° C. or from at least 550° C. to at most 600° C.

Carrying out the three deposition pulse less than 600° C. may provide the advantage of low temperature epitaxial formation, while providing still an acceptable growth rate for the epitaxial layers (20, 30, 40). Furthermore, it may allow for reducing the risk for stress relaxation, which may particularly be beneficial when forming thicker epitaxial stacks, such as for example, epitaxial stacks having more than 50 epitaxial pairs. It may further provide the advantage of reducing uniformity issues across the substrate in terms of such as, for example, thickness non-uniformity.

Even though at least an upper portion of the third epitaxial layer (40) may run the risk of getting oxidized while the wafer boat is being unloaded from the process chamber and/or while it is stationed on the carousel, the third semiconductor material comprised in the third epitaxial layer (40) may be chosen such that its oxide can be removed by performing a thermal treatment at a temperature that falls within the temperature range of the formation of the epitaxial stack when the wafer boat is loaded back into the process chamber from the carousel. Thus, in embodiments, the thermal treatment may be performed at a temperature less than 600° C.

In embodiments, the thermal treatment may be at a temperature in the range of from at least 300° C. to at most 600° C., or from at least 300° C. to at most 350° C., or from at least 350° C. to at most 400° C. or from at least 400° C. to at most 450° C. or from at least 450° C. to at most 500° C. or from at least 500° C. to at most 550° C. or from at least 550° C. to at most 600° C.

Therefore, in preferred embodiments, the third semiconductor material comprised in the third epitaxial layer (40) may be Ge. A germanium oxide layer is formed when the surface of the Ge layer, being the third epitaxial layer (40), is oxidized. However, this germanium oxide layer may be removed upon formation of a thermal treatment at temperatures above 430° C.

In embodiments, the method may further comprise, after loading (133) the wafer boat comprising the cooled plurality of substrates back in the process chamber, increasing temperature in the process chamber to the first deposition temperature or the second deposition temperature.

After the plurality of substrates comprised in the wafer boat is loaded back in the process chamber, the epitaxial growth may thus, continue. In embodiments where, the desired thickness of the second epitaxial layer (30) has been achieved before performing the third deposition pulse, the temperature of the process chamber may then be increased to the first deposition temperature in order to continue the epitaxial growth by forming the first epitaxial layer (20), after loading the wafer boat back in the process chamber. In embodiments where, the desired thickness of the second epitaxial layer (30) has not been achieved before performing the third deposition pulse, the temperature of the process chamber may then be increased to the second deposition temperature in order to continue and complete the epitaxial growth of the second epitaxial layer (30), after loading the wafer boat back in the process chamber.

Increasing the temperature in the process chamber to the first deposition temperature or the second deposition temperature may provide the advantage of facilitating the removal of the oxide layer that may have formed on at least the upper portion of the third epitaxial layer (40). Increasing the temperature in the process chamber to the first deposition temperature or the second deposition temperature may thus, correspond to performing the thermal treatment to remove the oxide layer on the at least upper portion of the third epitaxial layer (40).

It is to be understood that in embodiments, where the third semiconductor material comprised in the third epitaxial layer (40) is Ge, when the temperature in the process temperature is being raised back to the epitaxial formation temperature after the wafer boat is loaded (133) back into the process chamber, in order to resume epitaxial formation, the germanium oxide may evaporate already during the temperature increase, particularly when the temperature is thus, raised to or above 430° C.

Once the germanium oxide is removed during the temperature rise or during a specific thermal treatment performed at or higher than 430° C., the plurality of wafers comprised in the wafer boat may then be exposed to a gas ambient comprising a chlorine-containing compound, thereby removing the third epitaxial layer (40); i.e.: Ge, from the epitaxial stack (FIG. 4c). Removal of the third epitaxial layer (40) from the epitaxial stack may allow for exposing an upper surface of the second epitaxial layer (30). This advantageously allows for preparing the already formed epitaxial stack for further formation of the epitaxial pairs.

It is to be understood that the exposure to the gas ambient comprising the chlorine-containing compound allows for removing the unoxidized portion of the third epitaxial layer (40) in case of possible oxidation that may have taken place when the wafer boat was unloaded (132) from the process chamber to the carousel. In the absence of any oxidation to the third epitaxial layer (40), the exposure to the gas ambient comprising the chlorine-containing compound allows for removing the third epitaxial layer (40).

The growth of the epitaxial stack may thus, continue once the wafer boat is loaded (133) back into the process chamber until the threshold thickness is reached again (FIG. 4d). Upon reaching the threshold thickness again, the third epitaxial layer may then be provided (FIG. 4e).

It is to be understood that, in embodiments, the threshold thickness (t) obtained in the process chamber between each of unloading of the wafer boat from the process chamber (132) may be the same or different from another.

In embodiments, the chlorine-containing compound may be HCl or C12

In embodiments, the method may further comprise exposing the plurality of substrates comprised in the wafer boat to a reducing gas during unloading (132) the wafer boat from the process chamber and/or during loading (133) of the wafer boat back into the process chamber. In embodiments, the plurality of substrates comprised in the wafer boat may also be exposed to the reducing gas when stationed on the carousel, thus, in between unloading (132) from the process chamber and loading (133) back to the process chamber. Typically the wafer boat is exposed to an inert gas during unloading (132) of the wafer boat, during loading (133) of the wafer boat and during stationing of the wafer boat on the carousel. However, due to the possible presence of oxygen gas that may be comprised in the inert gas, the upper surface of the epitaxial stack may run the risk of getting oxidized. Oxidation of the upper surface of the epitaxial stack may jeopardize the further formation of the epitaxial layers once the wafer boat is loaded (133) back in the process chamber. This may be due to the fact that the oxide layer needs to be removed before continuing further with the formation of the epitaxial layers and this oxide removal process may lead to the formation of damages or defects on the upper surface of the epitaxial layer. The reducing gas may thus, advantageously allow for reducing the probability of oxidation during unloading (132) and/or loading (133) of the wafer boat.

In embodiments where, there may be the third epitaxial layer (40) on the epitaxial stack, exposure of the plurality of substrates to the reducing gas may thus, prevent the third epitaxial layer (40) from getting oxidized.

In embodiments, the exposure to the reducing gas may comprise providing the reducing gas by flowing the reducing gas in the process chamber prior to unloading (132) the wafer boat from the process chamber and/or prior to loading (133) of the wafer boat back into the process chamber. This may provide advantageously an additional precaution for reducing the probability of oxidation of the upper surface of the epitaxial stack. In this way, the wafer boat may be exposed to the reducing gas just before being unloaded in addition to being exposed to it while being unloaded. Furthermore, wafer boat may be exposed to the reducing gas just after being loaded in the process chamber in addition to being exposed to it while being loaded.

Thus, in embodiments, where the third epitaxial layer (40) may be provided on the exposed upper surface (31) before unloading (132), oxidation of an upper surface of this third epitaxial layer (40) may be reduced. In embodiments, where, in the absence of the third epitaxial layer (40), oxidation of the exposed upper surface (31) of the epitaxial stack may be reduced.

In embodiments, the method may further comprise exposing the plurality of substrates comprised in the wafer boat to the reducing gas while the wafer boat is stationed on the carousel. While the wafer boat is stationed on the carousel, a flow of inert gas is provided over the plurality of substrates to provide cooling to the substrates. However, the inert gas may comprise oxygen. This may make the upper surface of the epitaxial stack vulnerable to oxidation. Therefore, exposure of the plurality of substrates to the reducing gas, instead of the inert gas, while stationed on the carousel further allows for reducing the probability of oxidation.

In embodiments, the reducing gas may comprise H₂. This may help to remove or help to prevent the formation of the oxide layer on the exposed upper surface of the epitaxial stack, whether the exposed upper surface is comprised in the third epitaxial layer (40) or in the second epitaxial layer (31); i.e. in the absence of the provision of the third epitaxial layer (40) on the upper surface (31) of the epitaxial stack.

In embodiments, the reducing gas may be a mixture of H₂ and N₂. Thus, in embodiments, the reducing gas may be forming gas, with a H₂ content of 5 volume %. The H₂ content of 5 volume % may allow for safe processing in the semiconductor processing apparatus as further safety precautions may need to be taken at higher H₂ contents.

In embodiments of the present disclosure a method of reducing damage on a plurality of substrates during unloading from a wafer boat after processing in a semiconductor apparatus is disclosed. The method may comprise executing a method according to embodiments of the first aspect of the present disclosure. Damage on the plurality of substrates may be caused when the substrates are being unloaded from the wafer boat after processing is completed in the semiconductor processing apparatus. This may be due to the sticking or gluing of the substrates to the wafer boat supports comprised in the wafer boat. Sticking or gluing may occur as the epitaxial stack is formed on the plurality of substrates. This may, particularly, be of concern when forming thicker epitaxial stacks such as for example, having higher than 50 epitaxial pairs. Thus, sticking or gluing may lead to substrate damage or substrate breakage when unloading the substrates from the wafer boat. Thanks to the method disclosed the probability of sticking or gluing of the wafer boat supports, thus substrate damage or substrate breakage may advantageously be reduced.

In a second aspect of the present disclosure, a non-transitory readable medium is disclosed. The non-transitory readable medium may comprise instructions, which, when executed by a controller of a semiconductor processing apparatus, that may comprise a process chamber and a carousel, may cause the semiconductor processing apparatus to perform the following operations one of which may be loading a wafer boat into the process chamber. The wafer boat may comprise a plurality of substrates. The semiconductor processing apparatus may be a vertical or a horizontal apparatus. In some embodiments, the semiconductor processing apparatus is a vertical semiconductor processing apparatus and the process chambre may thus, extend in a vertical direction. The wafer boat may thus, extend in a vertical direction when placed in the process chamber.

Another operation may be processing the plurality of substrates in the process chamber, thereby forming, on the plurality of substrates, an epitaxial stack, the epitaxial stack having a pre-determined thickness, wherein the processing may comprise unloading the wafer boat, one or more times, from the process chamber to the carousel until the epitaxial stack reaches the pre-determined thickness.

The pre-determined thickness may refer to the desired thickness to be achieved of the epitaxial stack. The epitaxial stack may comprise epitaxial pairs, each pair comprising a first epitaxial layer and a second epitaxial layer. Thus, in embodiments, the pre-determined thickness may also refer to the thickness of the total number of epitaxial pairs of the epitaxial stack that is desired to be achieved. In embodiments, the number of epitaxial pairs may at least be 50.

In embodiments, the number of the epitaxial pairs (50) may go up to 550, but not limited thereto. Therefore, in some embodiments, the number of epitaxial pairs (50) may be at least from 50 to at most 150, or at least from 150 to at most 250 or at least from 250 to at most 350, or at least from 350 to at most 450 or at least from 450 to at most 550. This may allow for using the plurality of substrates having such an epitaxial stack for the manufacturing of, particularly, 3DDRAM devices, thereby overcoming the limits of planar scaling of these devices. It may thus, further contribute to commercial success.

Thus, in embodiments, the non-transitory readable medium that may comprise instructions, which, when executed by a controller of a semiconductor processing apparatus, that may comprise a process chamber and a carousel, may cause the semiconductor processing apparatus to perform the steps of the method disclosed according to the first aspect of this present disclosure.

This may thus, advantageously cause the semiconductor processing apparatus to process the plurality of substrates in such a way that after completion of the processing, a probability of substrate damage or substrate breakage is reduced when the plurality of substrates are being unloaded from the wafer boat. This may advantageously be due to the fact that unloading the wafer boat, one or more times, from the process chamber to the carousel until the epitaxial stack reaches the pre-determined thickness may allow for creating a chance for getting the substrates detached from the wafer boat supports. The chance for detachment may either be due to the cooling effect provided when the wafer boat comprising the plurality of substrates is stationed on the carousel or it may be done further by the substrate handling robot when it lifts and places back each of the plurality of substrates in the wafer boat when the wafer boat is stationed on the carousel.

Reducing the probability of substrate damage or substrate breakage may in turn advantageously provide for improvement in process throughput, process yield. This may further be particularly advantageous in the manufacturing of 3DDRAM devices. Furthermore, it may further be advantageous regarding the overall improvement in the throughput and yield of semiconductor manufacturing. Due to the reduced probability of substrate damage or substrate breakage, occurrence of unplanned maintenance cycles may thus, be avoided. This may further contribute to the improvement in individual process and overall semiconductor manufacturing throughput and yield.

In embodiments, the controller may comprise a processor. It may also comprise a memory and input/output devices being in communication with the processor. The memory may, in embodiments, contain one or more non-transitory memory such as for example, storage or one or more of transitory memory such as for example random access memory. The memory may, in embodiments, be a floppy disk, random access memory, read-only memory, hard disk or any other digital storage medium.

The operations to be carried out according to the present disclosure may be kept in the memory in the form of a software routine and when it is executed by the processor of the controller, the controller may then cause the semiconductor processing apparatus to perform the operations in the process chamber.

In a third aspect of the present disclosure a data processing system is disclosed. This data processing system may comprise a processor configure to perform the steps of loading a wafer boat into a process chamber comprised in a semiconductor processing apparatus. The wafer boat may comprise a plurality of substrates. In embodiments, the semiconductor processing apparatus may be a vertical or a horizontal apparatus. In some embodiments, the semiconductor processing apparatus is a vertical semiconductor processing apparatus and the process chamber may thus, extend in a vertical direction. The wafer boat may thus, extend in a vertical direction when placed in the process chamber.

Another operation may be processing the plurality of substrates in the process chamber, thereby forming, on the plurality of substrates, an epitaxial stack, the epitaxial stack having a pre-determined thickness. The semiconductor processing apparatus may further comprise a carousel. The carousel is for stationing the wafer boat before and after processing in the process chamber. The processing may comprise unloading the wafer boat, one or more times, from the process chamber to the carousel until the epitaxial stack reaches the pre-determined thickness.

The pre-determined thickness may refer to the desired thickness to be achieved of the epitaxial stack. The epitaxial stack may comprise epitaxial pairs, each pair comprising a first epitaxial layer and a second epitaxial layer. Thus, in embodiments, the pre-determined thickness may also refer to the thickness of the total number of epitaxial pairs of the epitaxial stack that is desired to be achieved. In embodiments, the number of epitaxial pairs may at least be 50.

In embodiments, the number of the epitaxial pairs (50) may go up to 550, but not limited thereto. Therefore, in some embodiments, the number of epitaxial pairs (50) may be at least from 50 to at most 150, or at least from 150 to at most 250 or at least from 250 to at most 350, or at least from 350 to at most 450 or at least from 450 to at most 550. This may allow for using the plurality of substrates having such an epitaxial stack for the manufacturing of, particularly, 3DDRAM devices, thereby overcoming the limits of planar scaling of these devices. It may thus, further contribute to commercial success.

This data processing system may advantageously provide for plurality of substrates having reduced probability for substrate damage or substrate breakage after processing is completed. This may in turn, improve the throughput and yield of the semiconductor processing apparatus as well as improving the overall throughout and overall yield for the semiconductor manufacturing. It may further provide the advantage of better scheduling of the maintenance cycles of the semiconductor processing apparatus due to the reduced probability of substrate damage or substrate breakage that may be unforeseen.

1. A method of forming an epitaxial stack on a plurality of substrates, the method comprising:
providing a semiconductor processing apparatus comprising a process chamber and a carousel for stationing a wafer boat before or after processing in the process chamber,
loading the wafer boat into the process chamber, the wafer boat comprising the plurality of substrates, and
processing the plurality of substrates in the process chamber, thereby forming, on the plurality of substrates, the epitaxial stack, the epitaxial stack having a pre-determined thickness,
wherein the processing comprises unloading the wafer boat, one or more times, from the process chamber to the carousel until the epitaxial stack reaches the pre-determined thickness.

2. The method according to claim 1, wherein the plurality of substrates comprised in the wafer boat are cooled when the wafer boat is stationed on the carousel after being unloaded from the process chamber.

3. The method according to claim 1, wherein the wafer boat comprises a plurality of wafer boat supports for supporting the plurality of substrates and the semiconductor processing apparatus further comprises a substrate handling robot and wherein the method further comprises, after unloading the wafer boat from the process chamber to the carousel:
lifting each of the cooled plurality of substrates using the substrate handling robot, thereby detaching each of the plurality of substrates from the wafer boat supports, and thereafter, and
placing each of the plurality of substrates back in the wafer boat.

4. The method according to claim 1, wherein the one or more times unloading of the wafer boat from the process chamber comprises obtaining the thickness of the epitaxial stack until it reaches the pre-determined thickness.

5. The method according to claim 1, wherein the processing further comprises loading the wafer boat comprising the cooled plurality of substrates from the carousel back into the process chamber.

6. The method according to claim 1, wherein the epitaxial stack comprises a plurality of epitaxial pairs, wherein each of the epitaxial pairs comprises a first epitaxial layer and a second epitaxial layer, the second epitaxial layer being different from the first epitaxial layer and being stacked alternately and repeatedly with the first epitaxial layer.

7. The method according to claim 6, wherein the processing further comprises, before and after each of the unloading of the wafer boat, performing a plurality of deposition cycles until the epitaxial stack has reached a threshold thickness being lower than the pre-determined thickness, wherein a deposition cycle comprises:
a first deposition pulse comprising a provision of a first reaction gas mixture to the process chamber, thereby forming the first epitaxial layer; and
a second deposition pulse comprising a provision of a second reaction gas mixture to the process chamber, the second reaction gas mixture being different from the first reaction gas mixture, thereby forming the second epitaxial layer.

8. The method according to claim 7, wherein the threshold thickness is in a range of 1 μm to 5 μm.

9. The method according to claim 7, wherein the first epitaxial layer comprises a first semiconductor material and wherein the provision of the first reaction gas mixture comprises providing first semiconductor material precursors and,
the second epitaxial layer comprises a second semiconductor material being different than the first semiconductor material and wherein the provision of the second reaction gas mixture comprises providing a second semiconductor material precursor.

10. The method according to claim 9, wherein the first semiconductor material precursors comprise a first germanium-containing compound and a first silicon-containing compound and wherein the second semiconductor material precursor comprises substantially a second silicon-containing compound.

11. The method according to claim 10, wherein the epitaxial stack has an exposed upper surface comprised in the second epitaxial layer upon reaching the threshold thickness, and
wherein the method further comprises, before unloading the wafer boat, at the threshold thickness, from the process chamber,
performing a third deposition pulse comprising a provision of a third reaction gas mixture to the process chamber, thereby forming a third epitaxial layer on the exposed upper surface of the epitaxial stack, the third epitaxial layer being different from the first epitaxial layer and different from the second epitaxial layer.

12. The method according to claim 11, wherein the provision of the third reaction gas mixture comprises providing a third semiconductor material precursor, the third semiconductor material precursor comprising substantially a second germanium-containing compound, the second germanium-containing compound being the same as or different from the first germanium-containing compound.

13. The method according to claim 11, wherein the first deposition pulse is carried out at a first deposition temperature, the second deposition pulse is carried out at a second deposition temperature, the third deposition pulse is carried out at a third deposition temperature and wherein the first, the second and the third deposition temperature is less than 600° C.

14. The method according to claim 13, wherein the method further comprises, after loading the wafer boat comprising the cooled plurality of substrates back in the process chamber,
increasing temperature in the process chamber to the first deposition temperature or the second deposition temperature, and
exposing the plurality of substrates to a gas ambient comprising a chlorine-containing compound, thereby removing the third epitaxial layer from the epitaxial stack.

15. The method according to claim 1, wherein the method further comprises exposing the plurality of substrates comprised in the wafer boat to a reducing gas during unloading the wafer boat from the process chamber and/or during loading of the wafer boat back into the process chamber.

16. The method according to claim 15, wherein exposure to the reducing gas comprises providing the reducing gas by flowing the reducing gas in the process chamber prior to unloading the wafer boat from the process chamber and/or prior to loading of the wafer boat back into the process chamber.

17. The method according to claim 15, wherein the method further comprises exposing the plurality of substrates comprised in the wafer boat to the reducing gas while the wafer boat is stationed on the carousel.

18. The method according to claim 1, wherein the semiconductor processing apparatus is a vertical furnace.

19. A non-transitory computer readable medium comprising instructions, which, when executed by a controller of a semiconductor processing apparatus, the apparatus comprising a process chamber and a carousel, causes the apparatus to perform operations of:
loading a wafer boat into the process chamber, the wafer boat comprising a plurality of substrates, and
processing the plurality of substrates in the process chamber, thereby forming, on the plurality of substrates, an epitaxial stack, the epitaxial stack having a pre-determined thickness,
wherein the processing comprises unloading the wafer boat, one or more times, from the process chamber to the carousel until the epitaxial stack reaches the pre-determined thickness.
